(19) United States
(12) Patent Application Publication
(10) Pub. No.: US 2012/0111397 A1
(43) Pub. Date: May 10, 2012

(54) KOHLER HOMOGENIZER FOR SOLAR CONCENTRATOR

(75) Inventors: Roland Winston, Merced, CA (US); Weiya Zhang, Merced, CA (US)

(73) Assignee: The Regents of the University of California

(21) Appl. No.: 13/192,634

(22) Filed: Jul. 28, 2011

Related U.S. Application Data
(60) Provisional application No. 61/369,586, filed on Jul. 30, 2010.

(51) Int. Cl. H01L 31/0232; F24J 2/00; F21L 4/00; H01L 31/02; G02B 3/00; G02B 17/08

(52) U.S. Cl. 136/255; 359/738; 359/731; 362/157; 136/259; 126/569

(57) ABSTRACT

An apparatus is disclosed including: an entrance aperture for admitting light from a source; an optical collector configured to receive light admitted through the entrance aperture and concentrate the light onto a receiver element; and an optical homogenizer element configured and arranged to image the entrance aperture onto the receiver element.

### CROSS-REFERENCE TO RELATED APPLICATION

This application claims priority under 35 U.S.C. §119(e) to U.S. Provisional Application No. 61/369,586, filed Jul. 30, 2010, the contents of which is incorporated by reference into the present application.

### BACKGROUND

The present disclosure relates generally to optical devices, and the concentration of light.

Solar cells for electrical energy production are very well known but have limited utility due to the very high cost of production. For example, although substantial research has been ongoing for many years, the cost per Kilowatt-hour (Kwh) still is about ten times that of conventional electric power production. To compete with wind power or other alternative energy sources, the efficiency of production of electricity from solar cells should be drastically improved.

Therefore it is desirable to provide optical systems and methods that overcome the above and other problems. In particular, it is desirable to provide systems and methods that enhance the efficiency of collection of solar energy.

### SUMMARY

In one aspect, the present disclosure provides systems and methods to concentrate light from a distant source, such as the sun, onto a target device, such as a solar cell.

Aspects of the present disclosure are directed to optical devices and systems that provide high solar flux onto a multi-junction solar cell, or other target cell, to produce efficient electrical output.

In one aspect, an apparatus is disclosed including: an entrance aperture for admitting light from a source; an optical collector (e.g., an imaging or non imaging concentrator) configured to receive light admitted through the entrance aperture and concentrate the light onto a receiver element; an optical homogenizer element configured and arranged to image the entrance aperture onto the receiver element.

In some embodiments, the optical collector concentrates the light into a beam having a waist region, and the optical homogenizer element is located proximal to the waist region.

In some embodiments, the entrance aperture, optical collector, optical homogenizer element and receiver element are disposed about an optical axis, and the entrance aperture and optical homogenizer element are rotationally asymmetric about the optical axis.

In some embodiments, shape of the entrance aperture corresponds to the shape of the receiver element. In some embodiments, the entrance aperture and receiver element are both square shaped.

In some embodiments, the collector includes a lens located proximal the input aperture. In some embodiments, the lens is characterized by an f-number of 1.0 or greater. In some embodiments, the lens in a Fresnel lens. In some embodiments, the lens is rotationally asymmetric about the optical axis. In some embodiments, the lens is square shaped. In some embodiments, the lens substantially overlaps the input aperture. In some embodiments, the lens is configured such that substantially all light rays incident on the outer edge of the lens at angles less than an acceptance angle are imaged onto the receiver element,

In some embodiments, the collector includes a two mirror Cassegrain type concentrator. In some embodiments, the two mirror Cassegrain type concentrator is substantially aplanatic.

In some embodiments, the optical homogenizer element is characterized by an f-number less than about 1, less than about 1.5, less than about 1, less than about 0.5, or even less.

In some embodiments, the collector has an acceptance angle of 1.0 degrees or greater, 1.5 degrees or greater, 2.0 degrees or greater, 5.0 degrees or greater, or even more.

In some embodiments, the collector concentrates light through the homogenizer element onto the receiver element with a concentration ratio of 500 or greater, 1000 or greater, 1500 or greater, 2000 or greater, or even more.

In some embodiments, the collector concentrates light through the homogenizer element onto the receiver element with a peak to average concentration ratio of 5.0 or less, 4,0 or less, 3.0 or less, 2.0, or less, or even about 1.0 (corresponding to uniform illumination).

Some embodiments include an optical system including the collector and homogenizer element, the optical system being characterized by a an optical efficiency of 80% or greater, 90% or grater, 85% or greater, or even greater.

In some embodiments, the optical homogenizer element and the receiver element are housed in an integrated housing. In some embodiments, the housing is a can type housing.

In some embodiments, the optical homogenizer element is configured such that substantially no light passing through the homogenizer element onto the receiver element is reflected at a total internal reflection interface.

In some embodiments, the receiver element includes an energy converting element adapted to absorb light and output energy in response to the absorbed light. In some embodiments, the energy converting element outputs electrical energy in response to the absorbed light. In some embodiments, the energy converting element includes a photovoltaic cell, e.g., a single or a multi-junction photovoltaic cell. In some embodiments, the energy converting element produces thermal energy in response to the concentrated light.

In some embodiments, the receiver element includes a photodiode; a laser gain medium; a photographic medium; a digital imaging sensor, a digital light processor, or a MEMs device.

In some embodiments, the receiver includes a light emitting element, and where the collector and the homogenizer element cooperate to collect emitted light from the light emitting element and form a beam of emitted light which is output from the input aperture. In some embodiments, the beam is substantially collimated. In some embodiments the divergence angle of the beam is less than 5 degrees, less than 2.5 degrees, less than 1 degree, or less. In some embodiments, the light emitting element includes a light emitting diode, an organic light emitting diode, a laser, or a lamp.

In some embodiments, the apparatus concentrates light incident at angles less than an acceptance angle with a concentration ratio at or near the thermodynamic limit.

In another aspect, a method is disclosed including: receiving light from a source with an optical concentrator module including an apparatus of any of the types described herein; using the optical concentrator, concentrating light onto the receiver element; and using the receiver element, converting the concentrated light into another form of energy.

As used herein, the f-number of an optical element is defined as one half times the inverse of the numerical aperture NA of the element. For an optical element having an acceptance angle θ, and working in a media having an index of refraction n, the numerical aperture is given by NA=n sin θ.

Various embodiments may include any of the above described features, either alone, or in any suitable combination.

### BRIEF DESCRIPTION OF DRAWINGS

FIG. 1 is an illustration of an optical concentration device.

FIG. 2 is a ray trace of an optical concentration device illustrating the edge ray design principle.

FIG. 3 is a ray trace of an optical concentration device featuring two thin lenses.

FIG. 4A is a schematic showing at-waist placement of a homogenizer element in an optical concentration device.

FIG. 4B is a schematic showing off-waist placement of a homogenizer element in an optical concentration device.

FIG. 5 is a plot showing irradiance at the receiver element of the concentration device of FIG. 1. The left panel shows an grey scale irradiance intensity plot over the area of the receiver. The right panel shows a scale for the plot in the left panel.

FIG. 6 is a schematic of a two mirror Cassegrain type concentration device featuring homogenizer element,

FIG. 7 is a ray trace of an aplanatic two mirror Cassegrain type concentration device featuring a homogenizer element.

FIG. 8A is a plot showing irradiance at the receiver element of the concentration device of FIG. 7. The left panel shows an grey scale irradiance intensity plot over the area of the receiver. The center panel shows a scale for the plot in the left panel. The right panel shows three dimensional plot corresponding to the grey scale plot of the left panel.

FIG. 8B is a plot showing irradiance at the receiver element of the concentration device of FIG. 7. The left panel shows a grey scale irradiance intensity plot over the area of the receiver. The center panel shows a scale for the plot in the left panel. The right panel shows three dimensional plot corresponding to the grey scale plot of the left panel.

FIG. 9 is a schematic illustration of a housing for a homogenizer element and a receiver element.

### DETAILED DESCRIPTION

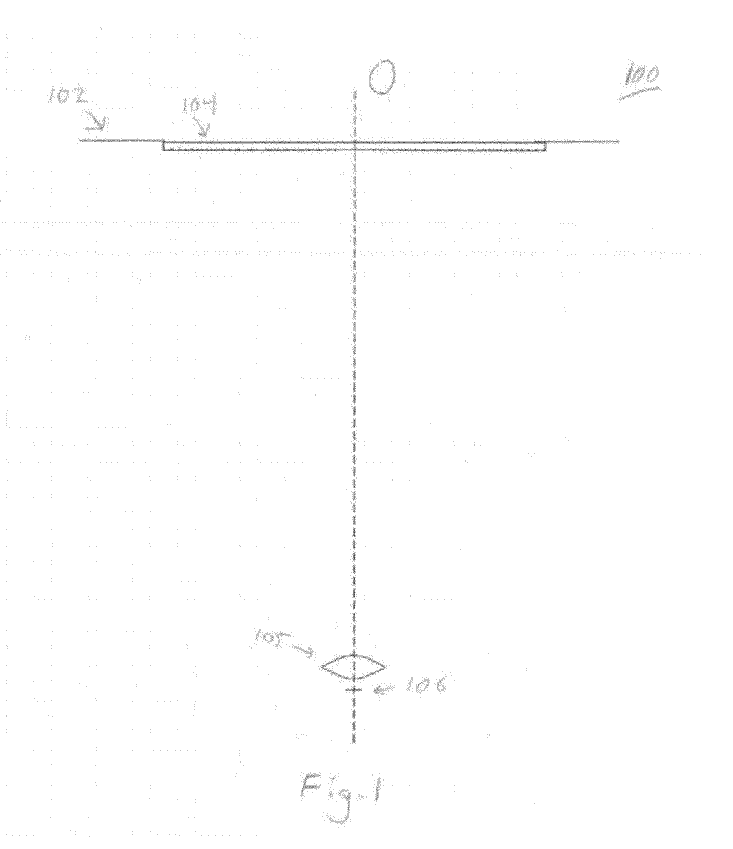

Referring to FIG. 1, a cross section is shown of optical device 100. Optical device 100 includes an entrance aperture 102 for admitting light from a source (e.g., the sun). Light admitted through the entrance aperture 102 passes through a collector 104 and is concentrated through an optical homogenizer element 105 to a receiver element 106 (e.g., a photovoltaic cell). The optical homogenization element 105 is an optical element which images input aperture 102 onto the receiver element 106.

As shown, the entrance aperture 102, collector 104, homogenizer element 105 and receiver element 106 are disposed about an optic axis O. In typical embodiments entrance aperture 102 may be rotationally asymmetric about the optic axis square shaped), however, other embodiments it may be symmetric (i.e., circular).

As shown, collector 104 is a lens, however, any other suitable refractive, reflective, diffractive (or combination thereof) imaging or non-imaging optical concentrator may be used (e.g. a Cassegrain concentrator, as described in detail below). In some embodiments, the lens has an f-number that is greater than about 1, e.g., between 1 and 4 or even greater. As shown, the lens is a substantially flat and square Fresnel lens positioned within and substantially filling a square shaped input aperture 102. Other embodiments my include curved Fresnel lenses, non-square, fiat Fresnel lenses, etc. In some embodiments, a flat cover (not shown), e.g., made of glass or PMMA or other suitable optically transparent material, is positioned on or proximal to the collector 104 on a side opposite the receiving element 106. The cover provides additional environmental protection for the collector 104 and allows the collector 104 to be very thin, e.g., a very thin layer.

As shown receiving element 106 is a photo-voltaic (PV) cell, e.g., a single or multi-junction silicon based PV cell. However, as suitable PV device know in the art may be used. Typically, the PV cell will have a form factor which is not rotationally symmetric about the optic axis, (e.g., a square shaped chip) although, in some embodiments, symmetric shapes may be used.

Homogenizer element 105 is an optical element which images the entrance aperture 105 onto the receiver element 106 (known in the art as a “Kohler” illumination configuration). As shown, homogenizer element 105 is an aspheric singlet lens. However, in other embodiments any other suitable optical element or combination of optical elements (refractive, reflective, diffractive, combinations thereof, etc.) may be used. In some embodiments, the homogenizer element 105 includes an anti-reflective (AR) coating to avoid losses due to reflection. Any suitable AR coating know in the art may be used.

The homogenizer element 105 may be used advantageously in applications where it is beneficial to “spread out” the irradiance more uniformly across receiver element 106. As is known in the art, many types of solar cells and other optical devices operate more efficiently When uniformly illuminated. For example, a typical solar cell may be suitable for use at concentrations of, e.g., up to a concentration C-500. However, when using conventional concentrators, even though the average concentration on the cell is below this limit, the device may be illuminated non-uniformly, e.g., such that solar light is concentrated to localized portions of the cell at concentrations significantly greater than C=500. This uneven concentration can lead to localized regions of high temperature on the cell, leading in turn to degraded performance and possible damage. In addition, localized high solar flux can cause electric breakdown of tunnel diode layers between junctions of a multi-junction cell degrading performance.

As discussed in greater detail below, in various embodiments, homogenizer element 105 produces desirably uniform irradiance distributions on the receiver element 106. For example, in some embodiments, the ratio of the peak concentration on the cell to the average concentration over the cell may be 5.0 or less, 4.0 or less, 3.0 or less, 2.0 or less, or even about 1.0 (corresponding to uniform illumination.)

Homogenizer element 105 provides an especially advantageous effect when shape of the input aperture 102 is well matched to the shape of the receiver element 106, e.g., in the case of a square shaped input aperture, and where the receiver element is square shaped PV solar cell. In such a case, in the absence of homogenizer element 105, the solar irradiance on the cell would have a circular, peaked distribution poorly matched to the shape of the cell. In contrast, by imaging the square shaped entrance aperture 102 onto the correspondingly square shaped receiver element 106, an irradiation distribution is provided which is well matched to the shape of the cell.

Notably, homogenizer element 105 may provide the advantageous irradiation, distributions described above with a relatively simple shape and compact form factor. For example, in typical embodiments, homogenizer 105 may be rotationally symmetric about the optic axis (e.g. as an aspheric singlet lens). The homogenizer element 105 may be shaped without any sharp features, and can operate, e.g., without requiring and total internal reflectance effects at its surfaces. Thus, the homogenizer element may have a shape suitable for fabrication using molding techniques known in the art. For example, the homogenizer element 105 may be fabricated by flowing molten glass into a form and allowing the glass to cool and solidify. In some embodiments, (e.g., for relatively low temperature concentration applications), the concentrator can be molded from acrylic, plastic, or other suitable material. In some embodiments the concentrator may be relatively short, e.g. characterized by an f-number of 2 or less, 1 or less, 0.5 or less, etc.

A person skilled in the art will appreciate that these features represent advantages over conventional optical mixers. Such mixers are typically refractive elements which are rotationally asymmetric about an optical axis. These devices receive light at an entrance face, mix incoming light using a multiple successive TIR (total internal reflection) reflections from lateral surfaces of the mixer, and output light with a more uniform distribution from an exit face. Typically, these mixers have complicated shapes which cannot be fabricated using molding techniques, requiring. Instead, more complicated and costly fabrication techniques such as precision grinding. Moreover, these mixers are typically very long, and cannot be used in high concentration systems (e.g., systems which provide concentration at or near the thermodynamic limit) while maintaining a small f-number (e.g. less that 0.5, less than 1.0, less than 2.0, etc.). Further, because the reliance on multiple TIR reflections, mixers of this type are often susceptible to performance degradation due to debris on or damage to the mixer's lateral surface.

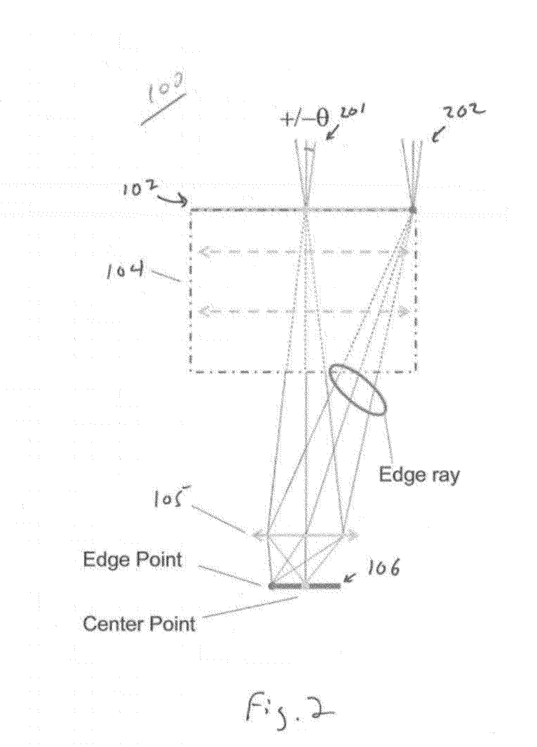

FIG. 2 shows a ray trace of an optical device 100 of the type shown in FIG. 1. A first set of rays 201 are shown incident on the center of the entrance aperture 102 at normal incidence and at angles equal to ±θ, where θ is the acceptance angle of the optical device 100. The first set of rays 201 are directed to the center point of receiver element 201. A second set of rays 202 are shown incident on the peripheral edge of the entrance aperture 102 at normal incidence and at angles equal to ±θ. This set of rays is referred to collectively as the “edge ray.” The collector 102 is chosen such that the edge ray is directed to a peripheral edge point of the receiver. As described, e.g., in Roland Winston et al, Nonimaging Optics, Academic Press (Elsevier) 2005, optical concentration systems which meet this so called “edge-ray condition” can provide concentration at or near the thermodynamic limit.

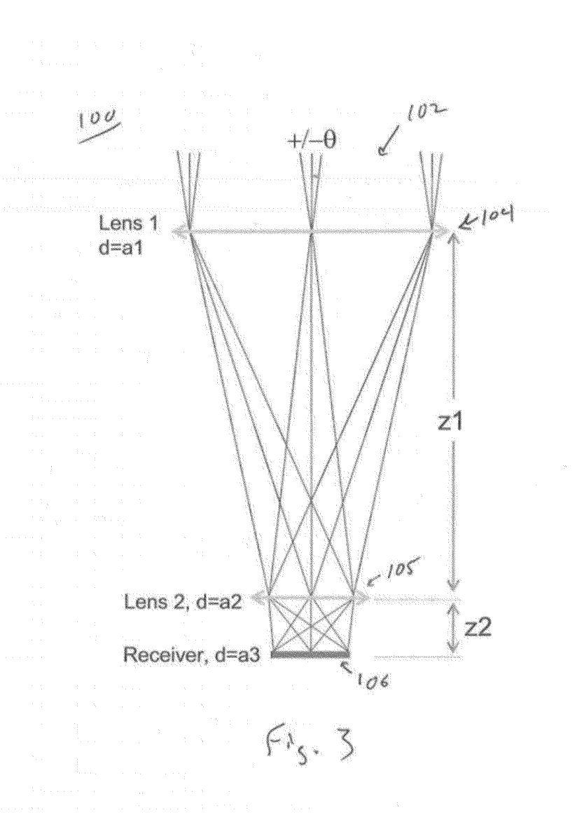

FIG. 3 is a ray trace illustrating the concentration of light by optical device 100 in the approximation that the collector 104 and the homogenizer element 105 are both thin lenses. In this approximation, for an acceptance angle θ, the concentration ration for optical device 100 is given by the equation:

$$C = \frac{1}{2 {F}_{2} \cdot θ} ,$$

where F₂ is the f-number of homogenizer element 105. Accordingly, for fixed acceptance angle θ, smaller f-number gives larger concentration.

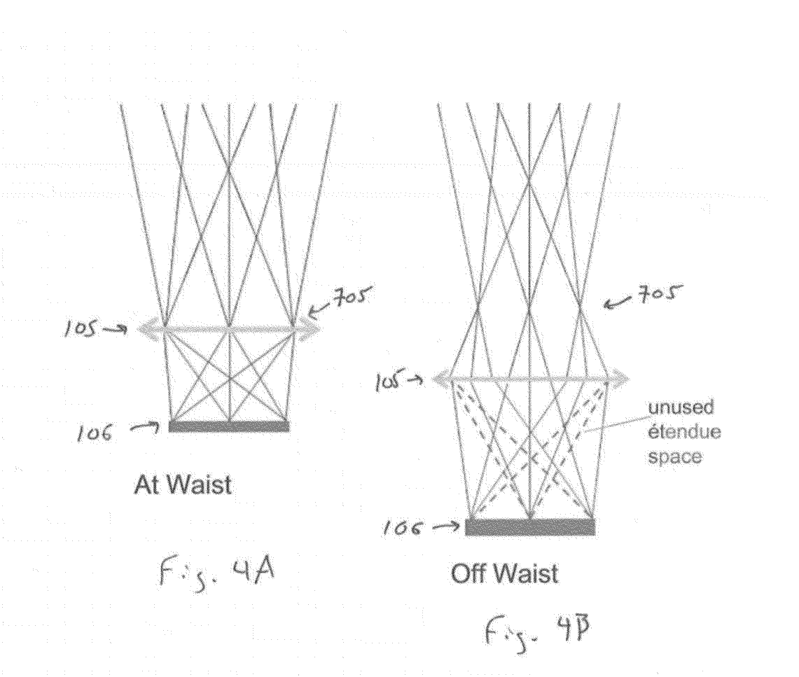

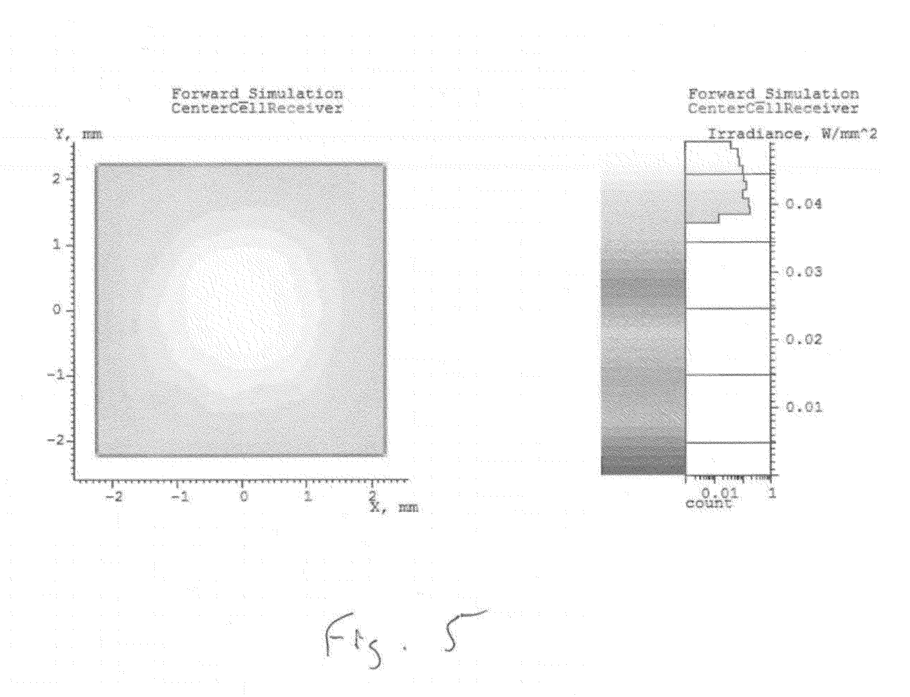

Referring to FIGS. 4A and 4B, the placement of the homogenizer element 105 can be seen to be an important design consideration. As illustrated, the light concentrated by collector 104 (not shown) forms a beam having a waist in waist region 705. As shown in FIG. 4B, if the homogenizer element 105 is located outside of the waist region 705, the concentration of the optical device 100 is degraded. Accordingly, to increase or maximize concentration, it is preferable to locate the homogenizer element 105 at the waist region 705, as shown in FIG. 4A. As will be understood by one skilled in the art, placement of the homogenizer 105 at the concentration region 705 corresponds to increasing or maximizing the use of the étendue space of the optical device 100.

In light of the above, a method of designing optical device 100 may be provided. First, a desired acceptance angle is chosen for the device 100. Second, the design of collector 104 is selected to well satisfy the edge ray condition, as described above. Third, the waist region 705 for the collector is determined (e.g., by ray tracing), and the position of the homogenizer element 105 is chosen to correspond to the positioned in the waist region 105. Fourth the shape, material, etc. of the homogenizer element is chosen (e.g., using any suitable optical design tools known in the art) such that the entrance aperture 102 is will imaged onto the receiver 106.

In some cases, aberrations in homogenizer element 105 may degrade the performance of optical concentrator 100, e.g., reducing the concentration or the acceptance angle, or impacting the uniformity or shape of the irradiance pattern. Taking aberrations into consideration, for a given collector 104, and a target acceptance angle and concentration, performance can be optimized as follows. The position and shape of the homogenizer element 105 serve as optimization values. Two merit conditions are used for the optimization. First, a good image is required of the peripheral edge point of the receiver element 106 (the edge ray condition shown with respect to the second set of rays 202 in FIG. 2). This condition corresponds to good concentration and large acceptance. Second, a good image is required of the center point of the receiver element 106 (e.g., as shown with respect to the first set of rays 201 in FIG. 2). This condition corresponds to uniformity of the irradiance pattern. In various embodiments, the relative weighting of the two conditions may be chosen to emphasize concentration and/or acceptance versus uniformity, as required by the application at hand.

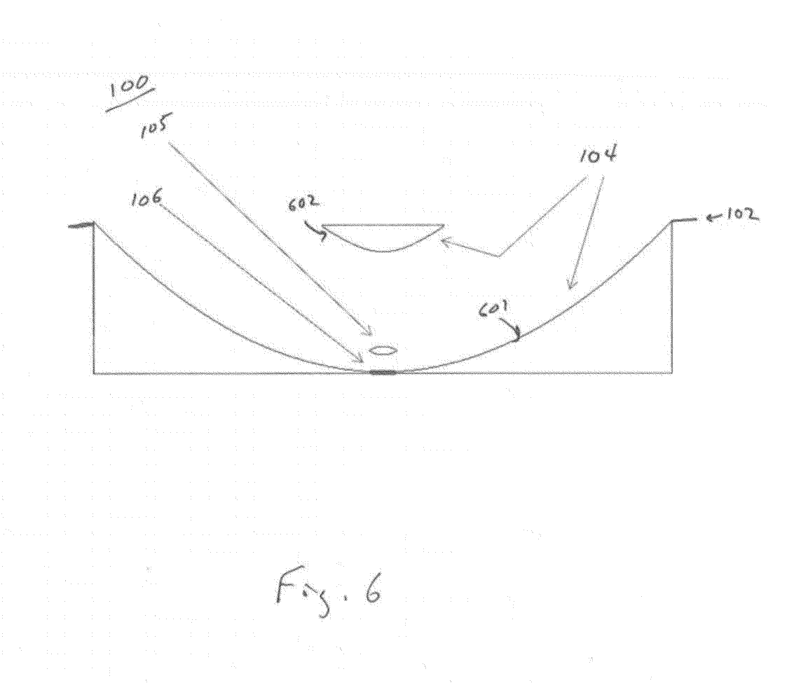

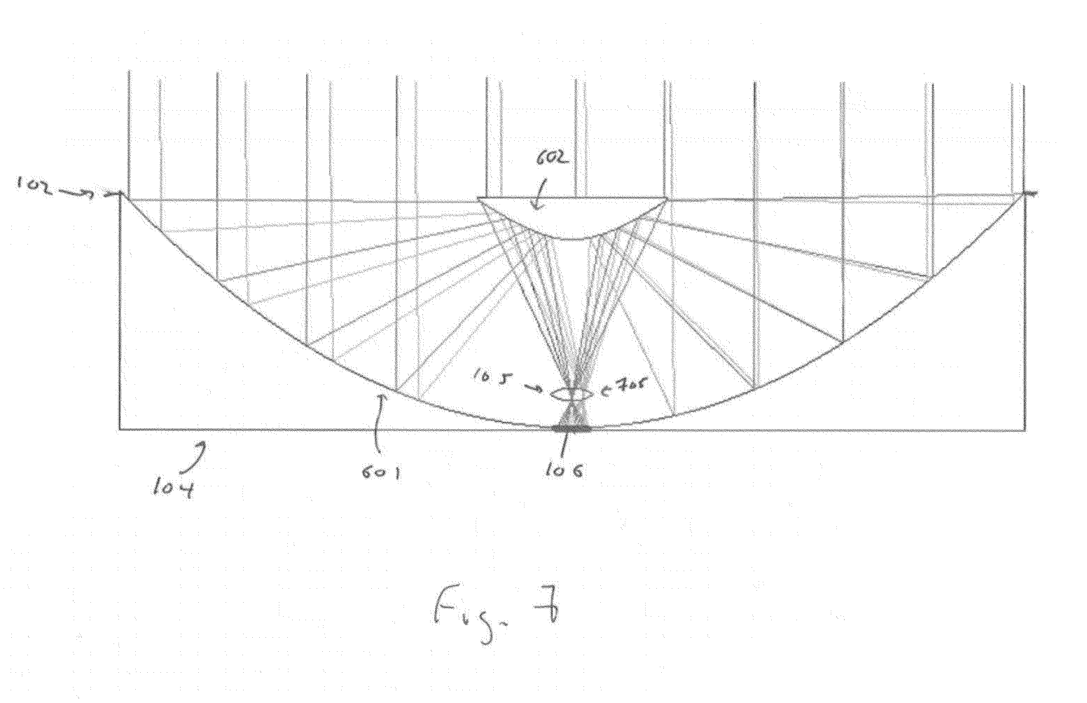

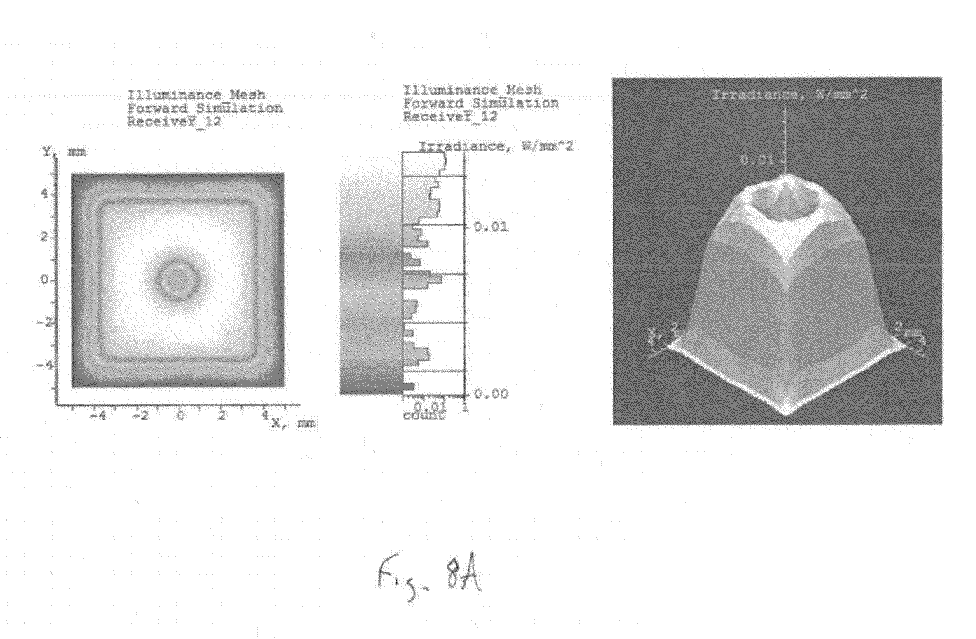

in one exemplary embodiment, a device 100 of the type shown in FIGS. 6 and 7 has an square entrance aperture 102 having dimensions of 102 mm×102 mm. The receiver element 106 is a 4.5 mm×4.5 mm square PV cell. Collector 104 is a Fresnel lens with a truncated square shape filling the entrance aperture 102. The Fresnel lens has a focal distance of 207 mm and an f-number of 1.2. This embodiment features an acceptance angle (determined as the angle at which the device operates with at least 90% of the optical efficiency provided at normal incidence) of 1.0 degrees, ad concentration ratio of C-711, and an optical efficiency of 86%. FIG. 5 illustrates the irradiance distribution at the receiver element 106 for normal incidence. Note the square shape of the irradiance pattern, corresponding to the imaging of the square entrance aperture 102 onto the receiver 106. Peak irradiation on the receiver element is approximately 700 suns for light at normal incidence and 1000 suns for light at the acceptance angle. Accordingly, a peak to average concentration ratio of is about 1000/C, or 1.4.

Referring to FIG. 6, an embodiment of optical device 100 is shown where the collector 104 is a two minor Cassegrain type concentrator. Light incident through the entrance aperture 102 reflects first from a primary reflector 601, is directed to reflect from a secondary reflector 602, and is concentrated through the homogenizer element 105 to the receiver element 106. As in the examples discussed above, the homogenizer element 105 images entrance aperture 102 onto receiver element 106 (e.g., a square shaped aperture may imaged onto a square shaped PV cell receiver). In some embodiments, e.g., as shown the collector 104 may be an aplanatic concentrator. For example, D. Lyndon-Bell, Monthly Notices of the Royal astronomical Society, vol. 334, pp. 787-796 (2002), describes an aplanatic concentrator featuring primary and secondary reflectors.

Referring to FIG. 7, a ray trace of the optical device 100 of FIG. 6 is shown. Darker lines indicate rays at normal incidence, while lighter lines correspond to rays incident at the maximum acceptance angle. Note that, the collector concentrates the incoming light into a beam having a waist at a waist region 705. As in the examples above, homogenizer element 105 is located at the waist region 705, thereby well utilizing &endue and providing good concentration.

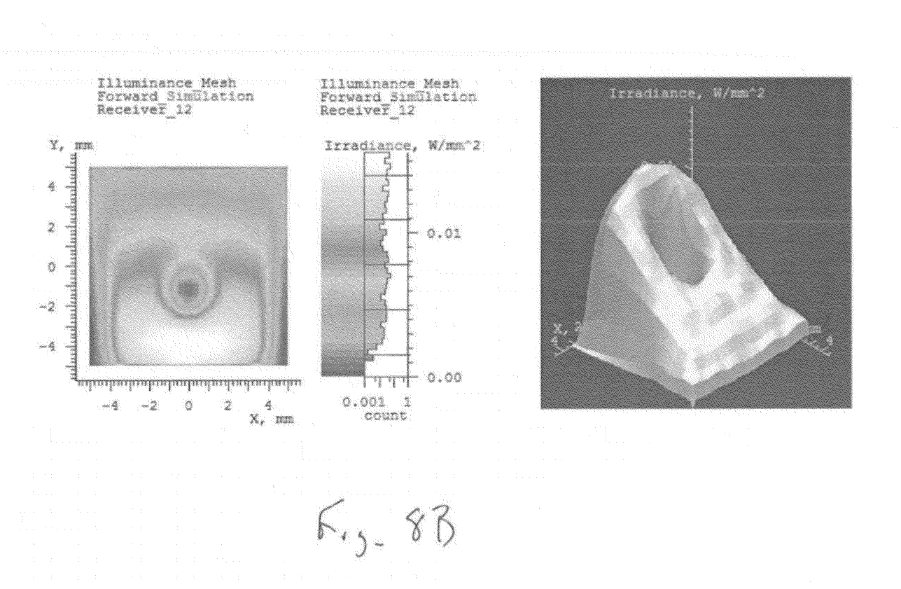

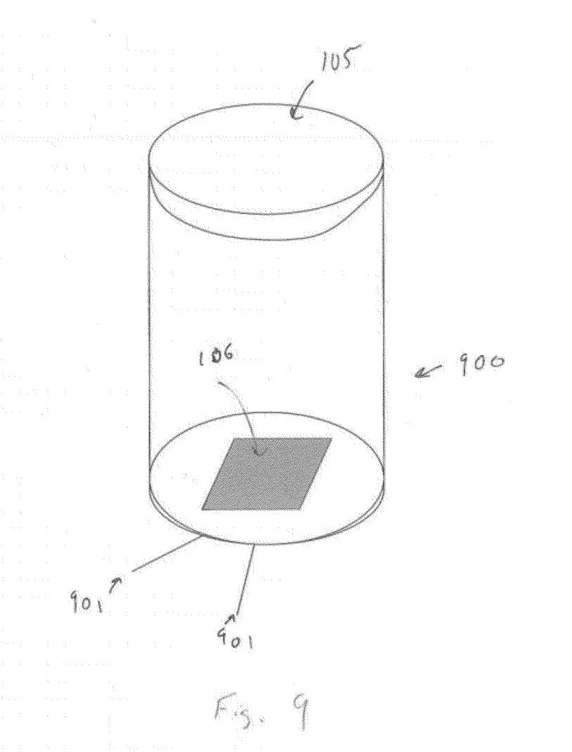

In one exemplary embodiment, a device 100 of the type shown in FIGS. 6 and 7 has an square entrance aperture 102 with dimensions of 247 mm×247 mm, the receiver element 106 is a 10 mm×10 mm square PV cell. The primary and secondary reflectors have a reflectance of 95%. This embodiment features an acceptance angle (determined as the angle at which the device operates with at least 90% of the optical efficiency provided at normal incidence) of 0.8 degrees, and concentration ratio of C=610, and an optical efficiency of 86%. FIGS. 8A and 9B illustrate the irradiance distribution at the receiver element 106 for normal incidence and incidence at 0.8 degrees, respectively. Note the square shape of the irradiance pattern, corresponding to the imaging of the square entrance aperture 102 onto the receiver 106. Peak irradiation on the receiver element is approximately 900 suns for light at normal incidence and 1000 suns for light at the acceptance angle. Accordingly, a peak to average concentration ration of is about 1000/C, or 1.6.

Referring to FIG. 9, in some embodiments, the homogenizer element 105 and the receiver element 106 are housed in a housing 900 to form an integral unit. As shown, the housing 900 is a can type-housing, e.g., of the type familiar in the semiconductor device packaging art. In some embodiments, the housing 900 includes leads 901 or other connectors allowing for electrical connection to receiver element 106. In some embodiments, the housing element may include a heat sink or other temperature control device (e.g., a thermoelectric cooler) in thermal communication with receiver 106. Note that, advantageously, homogenizer element 105 is not glued or otherwise affixed directly to receiver element 106. This obviates the disadvantages related to such glued interfaces including, e.g., thermal breakdown of the glue, etc.

Although several exemplary embodiments have been described, it is to be understood that optical device 100 and elements thereof may be provided with various suitable optical characteristics. In some embodiments, the optical homogenizer element 105 is characterized by an f-number less than about 1, less than about 1.5, less than about 1, less than about 0.5, or even less. In some embodiments, the collector 104 has an acceptance angle of 1.0 degrees or greater, 1.5 degrees or greater, 2.0 degrees or greater, 5.0 degrees or greater, or even more. In some embodiments, the collector 104 concentrates light through the homogenizer element 105 onto the receiver element with concentration ratio of 500 or greater, 1000 or greater, 1500 or greater, 2000 or greater, or even more. In some embodiments, the collector 104 concentrates light through the homogenizer element onto the receiver element with a peak to average concentration ratio of 5.0 or less, 4.0 or less, 3.0 or less, 2.0, or less, or even about 1.0 (corresponding to uniform illumination). In some embodiments, optical device 100 is characterized by a an optical efficiency of 80% or greater, 90% or grater, 85% or greater, or even greater.

Although the specific examples described above have dealt with concentrating radiation from a relatively large solid angle of incidence onto a relatively small target (e.g. concentrating solar light onto a solar cell), it will be understood that they may equally well be applied to broadcasting radiation from a relatively small source to a relatively large solid angle. (e.g. collecting light from an LED chip to form a beam or sheet of light). In some embodiments, the light is collected into a beam which is substantially collimated. In some embodiments the divergence angle of the beam is less than 5 degrees, less than 2.5 degrees, less than 1 degree, or less. The small source may, for example, include a light emitting diode, an organic light emitting diode, a laser, or a lamp.

One or more or any part thereof of the techniques described herein can be implemented in computer hardware or software, or a combination of both. The methods can be implemented in computer programs using standard programming techniques following the method and figures described herein. Program code is applied to input data to perform the functions described herein and generate output information. The output information is applied to one or more output devices such as a display monitor. Each program may be implemented in a high level procedural or object oriented programming language to communicate with a computer system. However, the programs can be implemented in assembly or machine language, if desired. In any case, the language can be a compiled or interpreted language. Moreover, the program can run on dedicated integrated circuits preprogrammed for that purpose.

Each such computer program is preferably stored on a storage medium or device (e.g., ROM or magnetic diskette) readable by a general or special purpose programmable computer, for configuring and operating the computer when the storage media or device is read by the computer to perform the procedures described herein. The computer program can also reside in cache or main memory during program execution. The analysis method can also be implemented, as a computer-readable storage medium, configured with a computer program, where the storage medium so configured causes a computer to operate in a specific and predefined manner to perform the functions described herein. In some embodiments, the computer readable media is tangible and substantially non-transitory in nature, e.g., such that the recorded information is recorded in a form other than solely as a propagating signal.

Note that as used herein, an acceptance angle should be taken as symmetric about zero, i.e., a device with an acceptance angle of 5 will accept light rays at angles ranging from −5 degrees to +5 degrees,

A number of embodiments of the invention have been described. Nevertheless, it will be understood that various modifications may be made without departing from the spirit and scope of the invention.

As used herein the term “light” and related terms (e.g. “optical”) are to be understood to include electromagnetic radiation both within and outside of the visible spectrum, including, for example, ultraviolet and infrared radiation.

In some embodiments, collectors of the type described herein may be designed by appropriate application of the “edge-ray” principal, e.g., as described in Roland Winston et al, Nonimaging Optics, Academic Press (Elsevier) 2005.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

All publications, patent applications, issued patents, and other documents referred to in this specification are herein incorporated by reference as if each individual publication, patent application, issued patent, or other document were specifically and individually indicated to be incorporated by reference in its entirety. Definitions that are contained in text incorporated by reference are excluded to the extent that they contradict definitions in this disclosure.

For the purposes of this disclosure and unless otherwise specified, “a” or “an” means “one or more.”

As used herein, the term “comprising” is intended to mean that the compositions and methods include the recited elements, but not excluding others, “Consisting essentially of” when used to define compositions and methods, shall mean excluding other elements of any essential significance to the combination for that intended purpose. “Consisting of” shall mean excluding more than trace elements of other ingredients and substantial method steps for making or using the concentrators or articles of this invention.

The construction and arrangements of the optical homogenizer, as shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Some elements shown as integrally formed may be constructed of multiple parts or elements, the position of elements may be reversed or otherwise varied, and the nature or number of discrete elements or positions may be altered or varied. The order or sequence of any process, logical algorithm, or method steps may be varied or re-sequenced according to alternative embodiments. Other substitutions, modifications, changes and omissions may also be made in the design, operating conditions and arrangement of the various exemplary embodiments without departing from the scope of the present disclosure.

What is claimed is;

1. An apparatus comprising;
an entrance aperture for admitting light from a source;
an optical collector configured to receive light admitted through the entrance aperture and concentrate the light onto a receiver element; and
an optical homogenizer element configured and arranged to image the entrance aperture onto the receiver element.

2. The apparatus of claim 1., wherein the optical collector concentrates the light into a beam having a waist region, and wherein the optical homogenizer element is located proximal to the waist region.

3. The apparatus of claim 2, wherein the entrance aperture, optical collector, optical homogenizer element and receiver element are disposed about an optical axis, and wherein the entrance aperture and optical homogenizer element are rotationally asymmetric about the optical axis.

4. The apparatus of claim 3, wherein shape of the entrance aperture corresponds to the shape of the receiver element.

5. The apparatus of claim 4, wherein the entrance aperture and receiver element are both square shaped.

6. The apparatus of claim 3, wherein the collector comprises a lens located proximal the input aperture.

7. The apparatus of claim 6, wherein the lens is characterized by an f-number of 1.0 or greater,

8. The apparatus of claim 6 or claim 7, wherein the lens in a Fresnel lens.

9. The apparatus of claim 6 or 7, wherein the lens is rotationally asymmetric about the optical axis.

10. The apparatus of claim 9, wherein the lens is square shaped.

11. The apparatus of claim 6 or 7, wherein the lens substantially overlaps the input aperture.

12. The apparatus of claim 11, wherein the lens is configured such that substantially all light rays incident on the outer edge of the lens at angles less than an acceptance angle are imaged onto the receiver element,

13. The apparatus of claim 3, wherein the collector comprises a two mirror Cassegrain type concentrator.

14. The apparatus of claim 13, wherein the two mirror Cassegrain type concentrator is substantially aplanatic.

15. The apparatus of claim 1, wherein the optical homogenizer element is characterized by an f-number less than about 1.

16. The apparatus of claim 1, wherein the optical homogenizer element is characterized by an f-number less than about 0.5.

17. The apparatus of claim 1, wherein the collector has an acceptance angle of 0.5 degrees or greater.

18. The apparatus of claim 1, wherein the collector has an acceptance angle of 1.0 degrees or greater.

19. The apparatus of claim 1, wherein the collector has an acceptance angle of 1.5 degrees or greater.

20. The apparatus of claim 1, wherein the collector concentrates light through the homogenizer element onto the receiver element with a concentration ratio of 500 or greater.

21. The apparatus of claim 1, wherein the collector concentrates light through the homogenizer element onto the receiver element with a concentration ratio of 1000 or greater.

22. The apparatus of claim 1, wherein the collector concentrates light through the homogenizer element onto the receiver element with a concentration ratio of 1500 or greater.

23. The apparatus of claim 1, wherein the collector concentrates light through the homogenizer element onto the receiver element with a concentration ratio of 2000 or greater.

24. The apparatus of claim 1, wherein the collector concentrates light through the homogenizer element onto the receiver element with a peak to average concentration ratio of 5.0 or less.

25. The apparatus of claim 1, wherein the collector concentrates light through the homogenizer element onto the receiver element with a peak to average concentration ratio of 4.0 or less.

26. The apparatus of claim 1, wherein the collector concentrates light through the homogenizer element onto the receiver element with a peak to average concentration ratio of 2.0 or less.

27. The apparatus of claim 1., wherein the collector concentrates light through the homogenizer element onto the receiver element with a peak to average concentration ratio of about 1.0.

28. The apparatus of claim 1, comprising an optical system comprising the collector and homogenizer element, the optical system being characterized by a an optical efficiency of 80% or greater.

29. The apparatus of claim 1, comprising an optical system comprising the collector and homogenizer element, the optical system being characterized by a an optical efficiency of 90% or greater.

30. The apparatus of claim 1, wherein the optical homogenizer element and the receiver element are housed in an integrated housing.

31. The apparatus of claim 30, wherein the housing comprises a can type housing.

32. The apparatus of claim 1, wherein the optical homogenizer element is configured such that substantially no light passing through the homogenizer element onto the receiver element is reflected at a total internal reflection interface.

33. The apparatus of claim 1, wherein the receiver element comprises an energy converting element adapted to absorb light and output energy in response to the absorbed light.

34. The apparatus of claim 33, wherein the energy converting element outputs electrical energy in response to the absorbed light.

35. The apparatus of claim 34, wherein the energy converting element comprises a photovoltaic cell.

36. The apparatus of claim 35, wherein the energy converting element comprises a multi-junction photovoltaic cell.

37. The apparatus of claim 33, wherein the energy converting element produces thermal energy in response to the concentrated light.

38. The apparatus of claim 1, wherein the receiver element comprises at least one selected from the list consisting of: a photodiode; a laser gain medium; a photographic medium; a digital imaging sensor, a digital light processor, and a MEMs device.

39. The apparatus of claim 1, wherein the receiver comprises a light emitting element, and wherein the collector and the homogenizer element cooperate to collect emitted light from the light emitting element and form a beam of emitted light which is output from the input aperture.

40. The apparatus of claim 39, wherein the beam is substantially collimated.

41. The apparatus of claim 40, wherein the light emitting element comprises at least one selected from the list consisting of: a light emitting diode, an organic light emitting diode, a laser, and a lamp.

42. The apparatus of claim 41, wherein the source is the sun.

43. A method comprising:
receiving light from a source with an optical concentrator module comprising the apparatus of claim 1;
using the optical concentrator, concentrating light onto the receiver element;
using the receiver element, converting the concentrated light into another form of energy.
